(19) United States
(12) Patent Application Publication
(10) Pub. No.: US 2025/0069957 A1
(43) Pub. Date: Feb. 27, 2025

(54) METHOD FOR MONITORING RUPTURE OF BONDING BUBBLE IN WAFER BONDING PROCESS DURING MANUFACTURING OF CHIPS

(71) Applicant: Shanghal Hual Integrated Circuit Corporation, Shanghal (CN)

(72) Inventor: Yurong Cao, Shanghal (CN)

(73) Assignee: Shanghal Hual Integrated Circuit Corporation, Shanghal (CN)

(21) Appl. No.: 18/672,121

(22) Filed: May 23, 2024

(30) Foreign Application Priority Data
Aug. 24, 2023 (CN) 202311075125.6

(51) Int. Cl. H01L 21/66; B24B 7/22; B24B 49/00; B24B 49/12; H01L 27/146

(52) U.S. Cl. CPC H01L 22/12; B24B 7/228; B24B 49/003; B24B 49/12; H01L 27/1469; H01L 27/1464

(57) ABSTRACT

This application discloses a method for monitoring if there is any ruptured bonding bubble in a wafer bonding process during manufacturing of a chip, including: bonding and fixing a front side of a first wafer to a back side of a second wafer to obtain a bonded wafer; after completing a grinding operation on the back side of the first wafer of the bonded wafer, inspecting the appearance and morphology of the back side of the first wafer, identifying if there is any ruptured bubble, and transmitting the bubble rupture signal to a processor in a case that the ruptured bubble is discovered. This application can allow for low-cost, simple, effective, and timely monitoring of bubble ruptures in a wafer grinding process in a non-invasive manner.

### CROSS-REFERENCE TO RELATED APPLICATIONS

This application claims the priority to Chinese patent application No. 202311075125.6, filed on Aug. 24, 2023, the disclosure of which is incorporated herein by reference in its entirety.

### TECHNICAL FIELD

This application relates to a semiconductor manufacturing technology, and in particular, to a method for monitoring whether a bonding bubble is ruptured in a wafer bonding process during manufacturing of chips.

### BACKGROUND

BSI (Back Side Illumination) process in manufacturing semiconductor image sensors is a widely used process for improving their performance

In order to improve the light sensitivity of CIS (Contact Image Sensor) chips, BSI CIS technology has emerged. The light sensing path of this type of products harvests light by the back side of the chip which is thinned to a few micrometers, thus greatly improving the light sensing capability.

The front stage processes of BSI CIS are similar to those of FSI (Front Side Illumination) CIS. The major differences of the wafer back stage process from the front process are in their docking process and thinning process. The BSI CIS process involves bonding the front side of a CIS wafer to a carrier wafer after a conventional front-end-of-line process similar to that of FSI CIS. The bonded wafer is then subjected to a grinding process on the back side of the CIS wafer down to several micrometers for further increasing the light harvesting efficiency, before completing BSI CIS.

During the BSI process, void defects can be generated when two wafers are bonded, so small bubbles occur between the two bonded wafers. Subsequently, when the wafer with a bubble defect passes through a grinding station, the bubble may be rupture by the grinding process. After this rupture, random falling of crystal slags can contaminate machines, which then scratch subsequent wafers, as illustrated in FIG. 1. When the ruptured wafer enters other machines later, crystal slags can fall and further contaminate those other machines. Therefore, to reduce the impact on subsequent wafers and machines, it is particularly important to monitor in real time if there are any ruptured bubbles after grinding.

A traditional method monitoring if there is any ruptured bubble is at the step of Si CMP (silicon Chemical Mechanical Polishing). After the front side of the CIS wafer is docked with the carrier wafer and a bonded wafer is formed, grinding is performed on the back side of the CIS wafer of the bonded wafer, which then goes through several processes before arrival at the CMP station for Si CMP operation. At this point, a defect inspection machine or an appearance inspection machine is used to exam the the post-CMP bonded wafer to check if there are any ruptured bubbles. Because the bonded CIS wafer has passed through several stations from backside grinding to CMP, the ruptured bubbles on the wafer might have already caused problems in post backside grounding wafers and machines.

### BRIEF SUMMARY

A method of chip manufacturing is provided for monitoring if there is any ruptured bubble in a wafer bonding process. This method allows for low-cost, simple, effective, and timely monitoring of bubble rupture during a wafer grinding process in a non-invasive manner.

The method for monitoring ruptured bubbles in the wafer bonding process:
S1: providing a first wafer and a second wafer that are required, and bonding the front side of the first wafer to a back side of the second wafer to obtain a bonded wafer;
S2: performing a grinding operation on the back side of the first wafer of the bonded wafer by using a grinding machine, the grinding machine being provided with a wafer appearance inspection device, a processor and an alarm device;
S3: after the grinding operation on the back side of the first wafer of the bonded wafer is completed, inspecting, by the wafer appearance inspection device, the appearance and morphology of the back side of the first wafer, identifying if any bubble is ruptured, and transmitting a bubble rupture signal to the processor in a case there is a ruptured bubble; and
S4: controlling, by the processor, the bonded wafer that which has completed the grinding operation to leave the grinding machine; and controlling, by the processor, the alarm device to give out an alarm in a case that the ruptured bubble signal is received.

According to some embodiments, in step S4, the processor controls the alarm device to give out an alarm and controls the grinding machine to stop in a case that the rupture signal is received.

According to some embodiments, in step S3, the wafer appearance inspection device further transmits to the processor the position of the bubble rupture on the back side of the first wafer;

In addition, the processor controls outputting the bubble rupture position to a display or memory.

According to some embodiments, the wafer appearance inspection device uses infrared light inspection or ultrasonic waves inspection scanning to determine the appearance and morphology of the back side of the first wafer and identify if the any bubble has ruptured.

According to some embodiments, the chip is a back side illumination contact image sensor chip;
herein photodiodes and a plurality of pixel transistors (units) of the contact image sensor are formed on the first wafer; and
herein a signal processing logic circuit of the contact image sensor is formed on the second wafer.

According to some embodiments, the chip is a back side illumination contact image sensor chip;
herein the contact image sensor is a four transistor (4T) structured CMOS image sensor. a photodiode, a transmission gate transistor, and a first floating diffusion area of each pixel unit of the contact image sensor are formed on the first wafer;
herein the photodiode is located at a longitudinal back of the first wafer;
herein the transmission gate transistor and the first floating diffusion area are located on a longitudinal front side of the photodiode;
herein the first floating diffusion area is located on a transverse peripheral side of the transmission gate transistor;
herein a source follower transistor, a reset transistor, a row selection transistor and a second floating diffusion area of each pixel unit are formed on the second wafer;
herein the first floating diffusion area and the second floating diffusion area are connected together through a through-silicon-via (TSV) to form a floating diffusion area of the pixel unit; and
herein the signal processing logic circuit of the contact image sensor is also formed on the second wafer.

According to some embodiments, longitudinal projections of the first floating diffusion area and the second floating diffusion area have an overlapping area.

The method for monitoring if the bonding bubble is ruptured in the wafer bonding process during manufacturing of the chip in this application can allow for low-cost, simple, effective, and timely monitoring of bubble ruptures in a wafer grinding process in an non-invasive manner, reduce the possibility of scratching subsequent wafers by the grinding machine, reduce the contamination to the subsequent machines, improve the fab production efficiency, and reduce the economic loss.

### BRIEF DESCRIPTION OF THE DRAWINGS

In order to describe the technical solution of this application more clearly, the drawings required for use in this application will be briefly introduced below. Apparently, the drawings described below are only some embodiments of this application. For those skilled in the art, other drawings may be obtained according to these drawings without contributing any inventive labor.

FIG. 1 is a schematic diagram that a subsequent wafer is scratched because crystal slag after bubble rupture contaminates a machine.

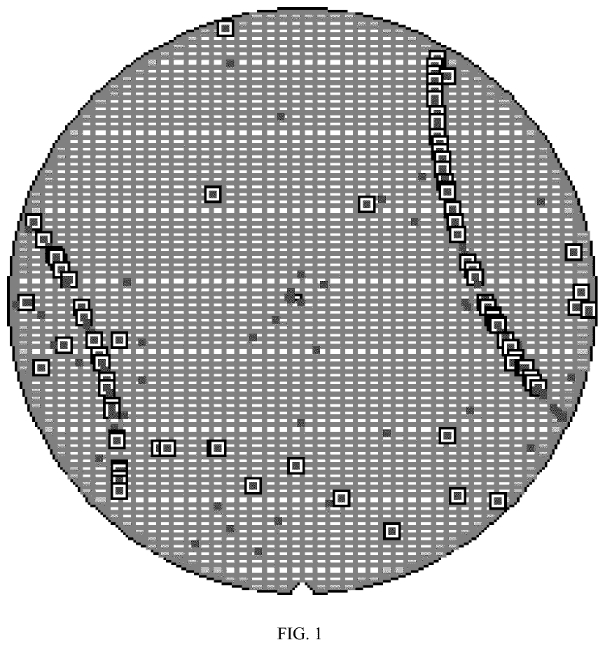

FIG. 2 is a flowchart of a method for monitoring if there are any ruptured bubbles in a wafer bonding process during manufacturing of a chip according to an embodiment of this application.

### DETAILED DESCRIPTION OF THE EMBODIMENTS

The technical solutions in the embodiments of this application will be described clearly and completely below with reference to the drawings in the embodiments of this application. Obviously, the described embodiments are only a part of the embodiments of this application, not all of them. Based on the embodiments of this application, all other embodiments obtained by those skilled in the art without contributing any inventive labor still fall within the scope of protection of this application.

The words such as “first” and “second” used in this application do not indicate any order, quantity, or importance, but are only intended to distinguish different components. The word such as “including” or “comprising” refers to that a component or object that appears before the word covers components or objects listed after the word and equivalents thereof, without excluding other components or objects. The word such as “connecting” or “connected” is not limited to physical or mechanical connection, but may include electrical connection, whether direct or indirect. “Up”, “down”, “left”, “right”, “front”, “back” and the like are only intended to indicate relative positional relationships. When the absolute position of a described object changes, the relative positional relationship may also change accordingly.

It should be noted that, without conflict, the embodiments and features in the embodiments of this application may be freely combined with each other.

### Embodiment 1

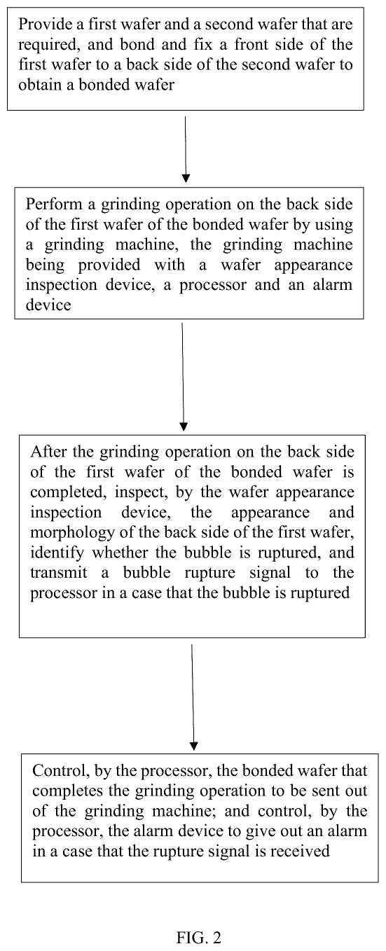

Referring to FIG. 2, a method for monitoring if there are any ruptured bubbles in a wafer bonding process during manufacturing of a chip includes the following steps:

In S1, providing a first wafer and a second wafer, and bonding a front side of the first wafer to a back side of the second wafer to obtain a bonded wafer.

In S2, performing a grinding operation on the back side of the first wafer of the bonded wafer by using a grinding machine. The grinding machine is provided with a wafer appearance inspection device, a processor, and an alarm device.

In S3, after the grinding operation on the back side of the first wafer of the bonded wafer is completed, the wafer appearance inspection device inspects the appearance and morphology of the back side of the first wafer, identifies if there is any ruptured bubble, and transmits a bubble rupture signal to the processor in a case there is the ruptured bubble.

In S4, the processor controls the bonded wafer that completes the grinding operation to leave the grinding machine; and the processor controls the alarm device to give out an alarm in a case that the rupture signal is received.

The method for monitoring if there is any ruptured bubble is in the wafer bonding process during manufacturing of the chip according to embodiment 1 will enable low-cost, simple, effective, and timely monitoring of ruptured bubbles in a wafer grinding process in an non-invasive manner, thus reducing the possibility of scratching wafers when the grinding machine grinds the subsequent wafers, reducing the contamination to the subsequent machines, so as to improve the fab production efficiency, and reduce the economic loss.

### Embodiment 2

Based on the method for monitoring if there are any ruptured bubbles in the wafer bonding process during manufacturing of the chip in embodiment 1, and
in step S4, the processor controls the alarm device to give out an alarm and controls the grinding machine to stop in a case that the rupture signal is received.

Exemplarily, in step S3, the wafer appearance inspection device further transmits the position of a bubble rupture on the back side of the first wafer to the processor;
the processor controls to output the position of the bubble rupture to a display or memory.

### Embodiment 3

Based on the method for monitoring if there are any ruptured bubbles in the wafer bonding process during manufacturing of the chip in embodiment 1, the wafer appearance inspection device applies an infrared inspection or a C-SAM (ultrasonic inspection) scanning to determine the appearance and morphology of the back side of the first wafer and identify whether any bubble is ruptured.

### Embodiment 4

Based on the method for monitoring if there are any ruptured bubbles in the wafer bonding process during manufacturing of the chip in embodiment 1, the chip is a BSI (Back Side Illumination) CIS (Contact Image Sensor) chip;
photodiodes and a plurality of pixel transistors of the CIS are formed on the first wafer; and
a signal processing logic circuit of the CIS is formed on the second wafer.

### Embodiment 5

Based on the method for monitoring whether the bonding bubble is ruptured in the wafer bonding process during manufacturing of the chip in embodiment 4, the chip is a BSI (Back Side Illumination) CIS (Contact Image Sensor) chip;
the CIS is a 4T structured CMOS image sensor, and a photodiode (PD), herein a transmission gate (TG) transistor and a first floating diffusion area of each pixel unit of the contact image sensor are formed on the first wafer;
the photodiode (PD) is located at a longitudinal back of the first wafer;
the transmission gate transistor (TG) and the first floating diffusion area are located on a longitudinal front side of the photodiode (PD);
the first floating diffusion area is located on a transverse peripheral side of the transmission gate transistor (TG);
a source follower transistor (SF), a reset transistor (RST), a row selection transistor (RS) and a second floating diffusion area of each pixel unit are formed on the second wafer;
the first floating diffusion area and the second floating diffusion area are connected together through a Through-Silicon-Via (TSV) to form a floating diffusion area (FD) of the pixel unit; and
the signal processing logic circuit of the CIS is also formed on the second wafer.

Exemplarily, longitudinal projections of the first floating diffusion area and the second floating diffusion area have an overlapping area.

In the method for monitoring whether the bonding bubble is ruptured in the wafer bonding process during manufacturing of the chip in Embodiment 5, since the photodiode (PD) of the CIS and other pixel transistors except the transmission gate transistor (TG) of the pixel unit are respectively located on the first wafer and second wafer, the area of the photodiode (PD) can be significantly increased, thus greatly increasing the full well capacitance of the image sensor (nearly double) and increasing the dynamic range. In addition, since pixel transistors other than the transmission gate transistor (TG) of the pixel unit are formed on the second wafer, the area of the photodiode (PD) only needs to strengthen the isolation from the transmission gate transistor (TG) and other pixel units, the isolation effect can be improved by increasing the P-type well isolation width, thus significantly reducing dark current and image noise, at the same time, dark line noise and full well capacitance will be increased, so the CMOS image sensor will generate less image noise at night or in other low light scenes. Moreover, since the transmission gate transistor (TG) and the photodiode (PD) are not formed on the same substrate where the source follower transistor (SF) is located, by increasing the size of the source follower transistor (SF), the optical signal processing capability of the image sensor under low light can be improved, the amplification performance of the source follower transistor (SF) can be improved, so the overall saturation signal quantity of the image sensor can be significantly increased, even doubled, compared to the traditional image sensor, reducing dark current and image noise, thus expanding the dynamic range of the image signals.

What are described above are only exemplary embodiment of this application and are not intended to limit this application. Any modifications, equivalent replacements, improvements and the like made within the spirit and principle of this application should be included within the scope of protection of this application.

What is claimed is:

1. A method for monitoring a ruptured bubble in a wafer bonding process during manufacturing a chip, comprising the following steps:
S1: providing a first wafer and a second wafer, and bonding and fixing a front side of the first wafer to a back side of the second wafer to obtain a bonded wafer;
S2: performing a grinding operation on a back side of the first wafer of the bonded wafer with a grinding machine, wherein the grinding machine comprises a wafer appearance inspection device, a processor, and an alarm device;
S3: after completing the grinding operation on the back side of the first wafer of the bonded wafer, inspecting an appearance and morphology of the back side of the first wafer with the wafer appearance inspection device, identifying if there is any ruptured bubble, and transmitting a bubble rupture signal to the processor in a case when the ruptured bubble is discovered; and
S4: after completing the grinding operation, controlling, by the processor, the bonded wafer to leave the grinding machine; and controlling, by the processor, the alarm device to give out an alarm in the case that the bubble rupture signal is received.

2. The method for monitoring the ruptured bubble in the wafer bonding process during manufacturing of the chip according to claim 1, wherein
in step S4, the processor controls the alarm device to give out an alarm and controls the grinding machine to stop in the case that the bubble rupture signal is received.

3. The method for monitoring the ruptured bubble in the wafer bonding process during manufacturing of the chip according to claim 1, wherein
in step S3, the wafer appearance inspection device further transmits a position of the bubble rupture on the back side of the first wafer to the processor; and
the processor controls to output the position of the bubble rupture to a display or a memory.

4. The method for monitoring the ruptured bubble in the wafer bonding process during manufacturing of the chip according to claim 1, wherein the wafer appearance inspection device applies infrared inspection or ultrasonic inspection scanning to determine the appearance and morphology of the back side of the first wafer and identify if there is any ruptured bubble.

5. The method for monitoring the ruptured bubble in the wafer bonding process during manufacturing of the chip according to claim 1, wherein
the chip is a back side illumination contact image sensor chip;
wherein photodiodes and a plurality of pixel transistors of the contact image sensor are formed on the first wafer; and
wherein a signal processing logic circuit of the contact image sensor is formed on the second wafer.

6. The method for monitoring the ruptured bubble in the wafer bonding process during manufacturing of the chip according to claim 1,
wherein the chip is a back side illumination contact image sensor;
wherein the contact image sensor is a four transistor (4T) structured CMOS image sensor, and
wherein a photodiode, a transmission gate transistor, and a first floating diffusion area of each pixel unit of the contact image sensor are formed on the first wafer;
wherein the photodiode is located at a longitudinal back of the first wafer;
wherein the transmission gate transistor and the first floating diffusion area are located on a longitudinal front side of the photodiode;
wherein the first floating diffusion area is located on a transverse peripheral side of the transmission gate transistor;
wherein a source follower transistor, a reset transistor, a row selection transistor, and a second floating diffusion area of each pixel unit are formed on the second wafer;
wherein the first floating diffusion area and the second floating diffusion area are connected together through a through-silicon-via to form a floating diffusion area of the pixel unit; and
wherein a signal processing logic circuit of the contact image sensor is also formed on the second wafer.

7. The method for monitoring the ruptured bubble in the wafer bonding process during manufacturing of the chip according to claim 6, wherein longitudinal projections of the first floating diffusion area and the second floating diffusion area have an overlapping area.
